(19) United States
(12) Patent Application Publication
(10) Pub. No.: US 2003/0179022 A1
(43) Pub. Date: Sep. 25, 2003

(54) Modulated current source difference mode emitter follower driver circuit

(76) Inventor: Robert Martin, Orlando, FL (US)

Correspondence Address: MORGAN & FINNEGAN, L.L.P., 345 Park Avenue, New York, NY, 10154-0053, US

(21) Appl. No.: 10/391,911

(22) Filed: Mar. 19, 2003

Related U.S. Application Data
(60) Provisional application No. 60/365,995, filed on Mar. 19, 2002.

(51) Int. Cl. H03B 1/00

(52) U.S. Cl. 327/112

(57) ABSTRACT

A driver circuit comprising has a pair of inputs, a pair of outputs, and multiple transistors, connected in a differential configuration, comprising a first set of transistors configured as a current mirror current source stage, a second set of transistors configured as a current source stage, and a third set of transistors configured as an emitter follower stage.

### CROSS REFERENCE TO RELATED APPLICATIONS

This application claims priority under 35 USC 119(e)(1) of U.S. Provisional Patent Application Ser. No. 60/365,995 filed Mar. 19, 2002.

### FIELD OF THE INVENTION

The present invention relates to driver circuitry and, more particularly, high bandwidth, low power driver circuitry.

### BACKGROUND

FIG. 1 is a conventional differential emitter follower difference mode line driver circuit. The typical load is a 100 ohm terminated electrical transmission line of the same characteristic impedance. The circuit has an incremental bandwidth of about 5.2 gigahertz and nominally uses about 31 milliwatts of power for a 3.3 volt supply. While this is acceptable for some applications, future needs will require greater bandwidth but less power.

The traditional circuit approach noted above suffers from problems related to power dissipation, gain, output impedance, and distortion.

Thus, there is a need in the art for a line driver circuit that has a higher bandwidth and uses less power, but without the level of distortion present in the prior art.

### SUMMARY OF THE INVENTION

The present invention relates to a type of driver circuit that provides a more efficient, current mode difference mode output amplifier design that has a wider bandwidth than available from conventional output stages. By virtue of this invention, the bandwidth to power ratio is improved by a factor of more than 3:1 over traditional designs.

The advantages and features described herein are a few of the many advantages and features available from representative embodiments and are presented only to assist in understanding the invention. It should be understood that they are not to be considered limitations on the invention as defined by the claims, or limitations on equivalents to the claims. For instance, some of these advantages are mutually contradictory, in that they cannot be simultaneously present in a single embodiment. Similarly, some advantages are applicable to one aspect of the invention, and inapplicable to others. Thus, this summary of features and advantages should not be considered dispositive in determining equivalence. Additional features and advantages of the invention will become apparent in the following description, from the drawings, and from the claims.

### BRIEF DESCRIPTION OF THE DRAWINGS

FIG. 1 is a conventional differential emitter follower difference mode line driver circuit of the prior art;

FIG. 2 is an exemplary circuit according to the present invention;

FIG. 3 is a graph comparing voltage gain vs. bandwidth for the circuits of FIG. 1 and FIG. 2.

### DETAILED DESCRIPTION

The invention relates to a type of driver circuit that provides a more efficient, current mode difference mode output amplifier design that has a wider bandwidth than available from conventional output stages.

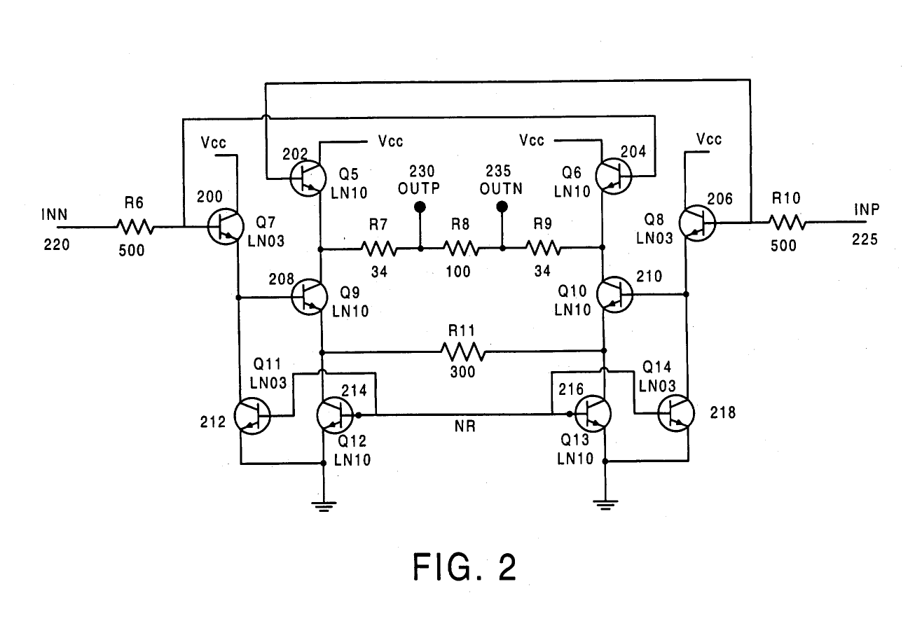

In accordance with the invention, the example circuit of FIG. 2 solves the power bandwidth problem by making the current source in the emitter follower active. In this way, its gain aids the emitter follower, which improves the bandwidth of the circuit. In addition, since the current of this source is made signal dependent, a current that is one-half of the peak load current is all that is needed as a quiescent current. Hence, wider bandwidth and reduced power consumption are realized.

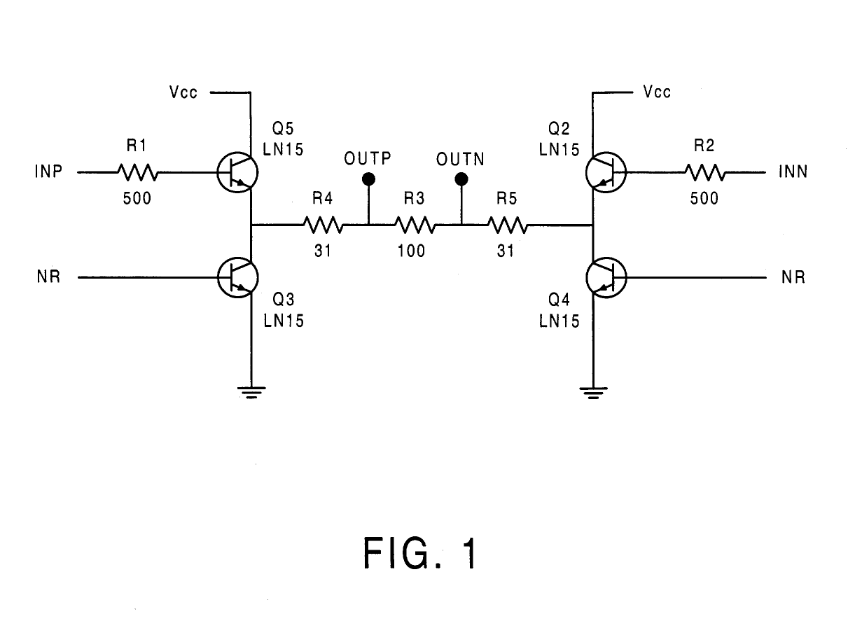

The driver circuit of FIG. 2 has the advantage of providing feedback for bandwidth adjustment. In addition, the circuit of FIG. 2 is configured so that, as the voltage demand increases, the shunt current in the long tail of the emitter follower decreases. Thus, the circuit of FIG. 2 may supply double the standby current. Furthermore, in the circuit of FIG. 2, the quality factor of the steady state frequency response is adjustable through resistor R11, a feature unavailable in the driver circuit of FIG. 1.

In FIG. 2, the transistors are, for purposes of illustration, of the type LN03 and LN10 which denote transistors in the 0.35 micron SiGe process family from Jazz Semiconductor, 4321 Jamboree Road, Newport Beach, Calif. 92660, and the resistors have the resistive values shown.

As illustrated in FIG. 2, the driver circuit includes transistors that may be grouped into three stages for the circuit. The first stage includes the transistors 200, 202, 204 and 206, which are configured as an emitter follower stage. The second stage, transistors 208, 210, are connected as a current source stage for supplying current for the third stage, a current mirror current source stage that includes transistors 212, 214, 216 and 218. The circuit is configured as a differential driver circuit and therefore has two signal inputs, a negative input 220 and a positive input 225. Accordingly, the circuit also includes two outputs situated across resistor R8, a positive output 230 and a negative output 235.

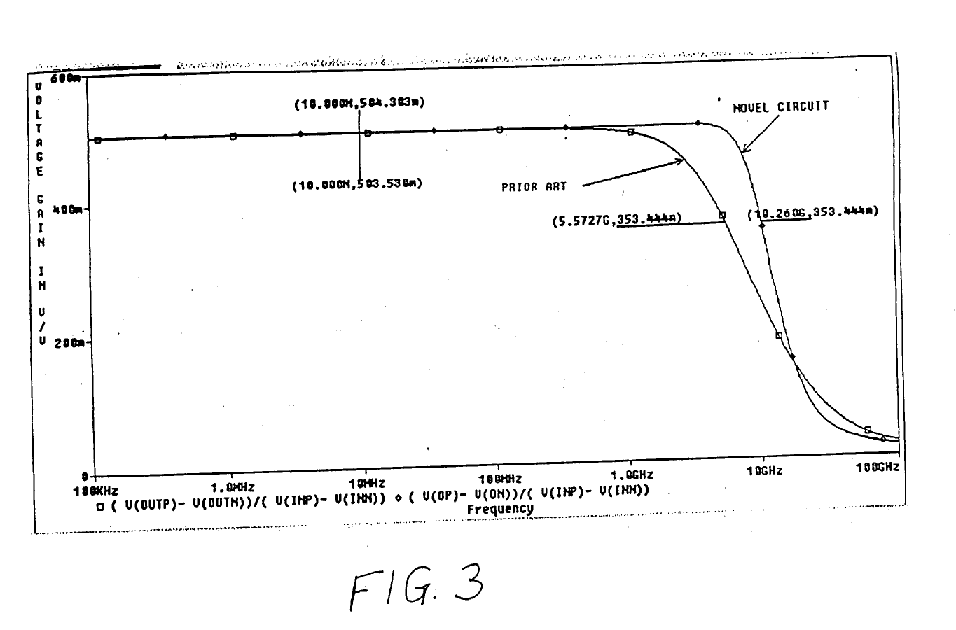

FIG. 3 is a graph comparing voltage gain (linear scale) vs. bandwidth (log scale) for the circuits of FIG. 1 and FIG. 2. As can be seen, the bandwidth of FIG. 2 is about 85% more than the bandwidth of the circuit of FIG. 1.

Through bread-boarding, using conventional discrete parts, and analysis using computer based circuit analysis tools, it has been determined, through measurement of the bread-boarded circuit and through analysis, that the quiescent power for this circuit is only 18.6 mW of power for a 3.3 volt supply and, through analysis, that the bandwidth is 10.26 GHz.

By way of comparison with the prior art, a circuit of the present invention uses 40% less current than the circuit of FIG. 1, while the bandwidth increases by about 85% over the circuit of FIG. 1. Moreover, in accordance with the invention, the bandwidth to power ratio of a circuit according to the present invention is improved by a factor of more than 3:1 over traditional designs.

It should be noted that different variants of the invention can be made, for example, by embodying a circuit according to the invention in a silicon-germanium or suitable similar silicon microchip, as well as in discrete and/or integrated circuit form through the straightforward use of other CMOS, BiCMOS, or other comparable low power devices.

It should be understood that the above description is only representative of illustrative embodiments. For the convenience of the reader, the above description has focused on a representative sample of all possible embodiments, a sample that teaches the principles of the invention. The description has not attempted to exhaustively enumerate all possible variations. That alternate embodiments may not have been presented for a specific portion of the invention, or that further undescribed alternate embodiments may be available for a portion, is not to be considered a disclaimer of those alternate embodiments. One of ordinary skill will appreciate that many of those undescribed embodiments incorporate the same principles of the invention and others are equivalent.

What is claimed is:

1. A driver circuit comprising:
multiple transistors connected in a differential configuration;
a first set of transistors, selected from among the multiple transistors, configured as a current mirror current source stage;
a second set of transistors, selected from among the multiple transistors, configured as a current source stage;
a third set of transistors, selected from among the multiple transistors, configured as an emitter follower stage;
the first, second and third sets of transistors being connected to each other such that
a) two transistors in the third set are both connected to a common transistor in the second set,
b) one of the two transistors in the third set that is connected to the common transistor in the second set is also connected to a transistor in the first set, and
c) a first resistor is connected in parallel between the first and second sets;
a pair of inputs, each of the inputs in the pair of inputs being connected to different transistors in the third set; and
a pair of outputs, each of the outputs being taken across opposite sides of a second resistor connected in parallel with transistors from both the second and third sets.

2. The driver circuit of claim 1, wherein the first set of transistors have a common base connection.

3. The driver circuit of claim 4, wherein each emitter of the transistors in the first set of transistors is connected to ground.

4. The driver circuit of claim 1, wherein the second resistor is one of three resistors connected in series.

5. The driver circuit of claim 4, wherein the other two of the three resistors have the same resistive value.

6. The driver circuit of claim 5 wherein a first of the other resistors is connected to one output in the pair and a second of the other resistors is connected to an other output in the pair.

7. The driver circuit of claim 1, wherein a transistor from the third set is connected to a base of a transistor in the second set.

8. The driver circuit of claim 7, wherein a different transistor from the third set is connected to a collector of a transistor in the second set.

9. The driver circuit of claim 1, wherein the inputs, outputs and multiple transistors all comprises a single integrated circuit.

10. The driver circuit of claim 9, wherein the integrated circuit comprises a silicon-germanium microchip.

11. The driver circuit of claim 1, wherein the transistors are CMOS elements.

12. The driver circuit of claim 1, wherein the transistors are BiCMOS elements.

13. A driver circuit comprising:
multiple transistors each having an emitter, a base and a collector, wherein a DC voltage source is connected to the respective collectors of a first, second, third, and fourth transistor of the multiple transistors;
the first and third transistor bases being connected to a first end of a first resistor, a second end of the resistor being connected to a negative input;
the second and fourth transistor bases being connected to a first end of a second resistor, a second end of the second resistor being connected to a positive input;
the emitter of the first transistor being connected to the base of a fifth transistor and the collector of a sixth transistor;
the emitter of the second transistor being connected to the collector of the fifth transistor and to a first end of a group of at least three resistors connected in series;
the emitter of the third transistor being connected to the collector of a seventh transistor and to a second end of the group of at least three resistors;
the emitter of the fourth transistor being connected to the base of the seventh transistor and the collector of an eighth transistor;
the emitter of the fifth transistor being connected to the collector of a ninth transistor and a resistor being connected to the emitter of the seventh transistor,
the emitter of the seventh transistor being connected to the collector of a tenth transistor;
the bases of each o f the sixth, eight, ninth and tenth transistors all being connected to each other;
the emitters of the sixth, eight, ninth, and tenth transistors all being connected to ground; and
an output taken across a resistor within the group of at least three resistors.

14. The driver circuit of claim 13, wherein the first, sixth, fourth, and eighth transistors all have substantially similar transistor characteristics.

15. The driver circuit of claim 13, wherein the second, third, fifth, seventh, ninth, and tenth transistors all have substantially similar transistor characteristics.

16. The driver circuit of claim 13, wherein the circuit comprises an integrated circuit.

17. The driver circuit of claim 16, wherein the integrated circuit comprises a silicon-germanium microchip.

18. The driver circuit of claim 17, wherein the transistors are CMOS elements.

19. The driver circuit of claim 17, wherein the transistors are BiCMOS elements.
